(19) United States
(12) Patent Application Publication
(10) Pub. No.: US 2026/0050046 A1
(43) Pub. Date: Feb. 19, 2026

(54) CALIBRATED ELECTRICAL CONTINUITY DETECTOR

(71) Applicant: DIT-MCO International LLC, Kansas City, MO (US)

(72) Inventor: David Alan Shier, Lee's Summit, MO (US)

(21) Appl. No.: 19/300,167

(22) Filed: Aug. 14, 2025

Related U.S. Application Data
(60) Provisional application No. 63/683,921, filed on Aug. 16, 2024.

(51) Int. Cl. G01R 31/54

(52) U.S. Cl. CPC G01R 31/54

(57) ABSTRACT

A continuity detector for determining the continuity of a Unit Under Test (UUT). The detector comprises a housing defining an interior volume, an electronics package disposed within the interior volume defined by the housing assembly, a first test contact and a second test contact to interface with the electrical wire or harness assembly, a precision resistance standard disposed within the housing and electrically coupled to the electronics package, and a power source disposed within the housing assembly. The first test contact and the second test contact are external to the interior volume. The first test contact and the second test contact are electrically coupled to the electronics package. The electronics package comprising a resistance measurement device and a comparator circuit. The comparator circuit is configured to determine if the resistance of the UUT is greater than, less than, or equal to the resistance of the resistance standard.

### CLAIMS OF PRIORITY

This application claims the benefit of U.S. Provisional Application No. 63/683,921, filed Aug. 16, 2024, the content of which is herein incorporated by reference in its entirety.

### FIELD

Embodiments herein relate to systems and methods that test electrical wiring for continuity.

### BACKGROUND

In the manufacturing or installation of electrical wiring systems and harnesses, it is often necessary to verify the connection of single wires or conductors to assure that they are terminated properly. Devices that check for such continuity do not indicate a specific resistance value which might be specified by the design requirements of the Unit Under Test (UUT) or Device Under Test (DUT). Such devices only indicate if electrical activity is present. Such devices are adequate for basic “go/no-go” decisions regarding the connection or disconnection of a conductor, but are not useful in assuring that the connection meets the resistance specifications of the product (i.e., that the conductor is properly connected electrically).

In some applications, a calibrated ohmmeter may be used to measure the specific resistance value. However, such devices do not provide a specific pass/fail threshold and cannot ensure that the user is measuring to the required specification.

### SUMMARY

A device which combines the simplicity of a pass/fail style continuity checker with the parametric measurement capability of a resistance meter is provided herein. Various embodiments described herein provide such a calibrated continuity checker by incorporating a precision reference resistor that is compared to the unknown to determine if the resistance value of the unknown is greater than, equal to, or less than the pass/fail threshold. In various embodiments, the threshold is set by the precision reference resistor that is included in the continuity checking device. In this disclosure, precision reference resistor, reference resistor, precision reference standard can be used interchangeably.

Since the length of the test leads can vary widely, in some embodiments disclosed herein, the two leads are connected together during a calibration cycle so that their resistance does not affect the measurement. In various embodiments, it is possible to utilize four-wire (Kelvin) probes, such that the resistance of the probe wire is not included in the measured value. In still other embodiments, the resistance standard (i.e. calibration resistor or precision reference resistor) can be directly compared to the UUT using an analog or digital comparator. Such designs can eliminate the need for a “CAL switch” and related calibration cycle. In order to eliminate the requirement for compensation of the resistance of the test leads, a four-wire “Kelvin” test lead or probe can be included in various embodiments.

Various embodiments provide a continuity detector for determining the continuity of an electrical wire or harness assembly. The continuity detector can include a handheld housing assembly defining an interior volume; an electronics package disposed within the interior volume defined by the housing assembly, the electronics package comprising a resistance measurement device and a comparator circuit; one or more pass/fail indicators electrically coupled to the electronics package and disposed on the housing assembly or in the housing assembly; a first test contact and a second test contact configured to interface with the electrical wire or harness assembly, wherein the first test contact and the second test contact are external to the interior volume, wherein the first test contact and the second test contact are electrically coupled to the electronics package; a precision resistance standard disposed within the housing and electrically coupled to the electronics package; a power source disposed within the housing assembly, wherein the power source is electrically coupled to the electronics package; wherein the electronics package is configured to send a first signal to the first test contact and to measure a return signal at the second test contact, and the electronics package is configured to send a second signal to the precision resistance standard and to measure the signal after the precision resistance standard; and wherein the comparator circuit is configured to determine if the resistance of the electrical wire or the harness assembly is greater than, less than, or equal to the resistance of the precision resistance standard.

In various embodiments, the first signal and the second signal are identical.

In various embodiments, the one or more pass/fail indicators are activated only if the resistance of the wire under test or the harness assembly is less than or equal to the resistance of the precision resistance standard.

In various embodiments, the comparator circuit is configured to directly compare the resistance of the precision resistance standard to the resistance of the electrical wire or the wire harness assembly.

In various embodiments, first test contact and the second test contact are connected via a Kelvin connection comprising four-wire test leads, such that the resistance of the test contacts does not impact the comparison of resistance.

In various embodiments, the electronics package comprises data related to the total resistance of circuitry including test leads, the first and second test contacts and the internal precision resistance standard.

In various embodiments, electronics package is configured to update the data related to the total resistance of the circuitry on a periodic basis such that the resistance of the test leads do not impact the comparison of the resistance of the electrical wire or wire harness, and the resistance of the precision resistance standard.

In various embodiments, the precision resistance standard is at least 5 ohms and not more than 25 ohms.

In various embodiments, the one or more pass/fail indicators comprise at least one of a visual indicator and an audible indicator.

In various embodiments, the visual indicator comprises a light emitting diode (LED).

In various embodiments, the audible indicator comprises a buzzer.

In various embodiments, the pass/fail indicators provide a binary output, indicating only a pass or a fail condition to a user.

In various embodiments, the continuity detector does not display a numerical resistance value to a user.

In various embodiments, the detector further comprises a rechargeable battery as the power source.

In various embodiments, the detector further comprises a charging port electrically coupled to the rechargeable battery.

In various embodiments, the charging port comprises a Universal Serial Bus (USB) port.

In various embodiments, at least one of the first test contact or the second test contact is removably attached to the housing assembly.

In various embodiments, the electronics package includes an electrostatic discharge (ESD) protection circuit electrically coupled to at least one of the first test contact or the second test contact.

In various embodiments, the ESD protection circuit comprises at least a transient voltage suppression diode and a series inductor.

In various embodiments, the precision resistance standard is a resistor selected during manufacture to define the threshold resistance for a predetermined application.

In various embodiments, the electronics package comprises a microcontroller configured to receive an output from the comparator circuit and to activate the one or more pass/fail indicators based on whether the measured resistance is less than or equal to the resistance of the precision resistance standard.

In various embodiments, the handheld housing assembly includes a removable cap for access to the power source.

In various embodiments, the electronics package is configured to operate with a non-rechargeable battery as the power source.

In various embodiments, the electronics package comprises a current source configured to supply a constant current through the electrical wire or harness assembly under test.

In various embodiments, the first test contact and the second test contact are each connected to the electronics package by flexible leads.

In various embodiments, the electronics package comprises a Kelvin double bridge circuit.

In various embodiments, the resistance value of the precision resistance standard is fixed and cannot be adjusted by a user.

In various embodiments, either or both of the first test contact and the second test contact comprise a clip.

In various embodiments, the handheld housing assembly further comprises an ergonomic grip surface to facilitate comfortable manual operation.

In various embodiments, the housing assembly further comprises a belt clip for attachment to a user's clothing or tool belt.

In various embodiments, the first test contact and the second test contact are color-coded to indicate polarity or connection order.

In various embodiments, the electronics package is configured to automatically power off after a predetermined period of inactivity to conserve battery life.

In various embodiments, the electronics package further comprises a low-battery indicator disposed on or in the housing assembly.

In various embodiments, the electronics package includes a temperature compensation circuit to account for resistance changes due to ambient temperature variations.

In various embodiments, the pass/fail indicators further comprise a vibration motor for providing haptic feedback to the user.

In various embodiments, the housing assembly is formed from a material having a dielectric strength of at least 20 kV/mm.

In various embodiments, the housing assembly includes an ingress protection rating of at least IP54.

Various embodiments provide a method for determining the continuity of an electrical component. The method can include contacting the electrical component with a first test contact of a continuity detector; sending a first signal from an electronics package within the continuity detector to the first test contact; sending a second signal to a precision resistance standard within the continuity detector; measuring a return signal of the first signal by contacting the electrical component with a second test contact of the continuity detector; measuring a return signal of the second signal on the opposite side of the precision resistance standard from where the second signal was sent; comparing the measured return signal of the first signal with the measured return signal of the second signal; and activating a pass/fail indicator in response to the comparison of the measured return signals.

In various embodiments, the first signal and the second signal are sent at the same time.

In various embodiments, the first signal and the second signal are the same signal. In various embodiments, the first signal and the second signal have the same voltage.

In various embodiments, the pass/fail indicator is only activated when the measured return signal of the first signal represents equal or less resistance than the measured return signal of the second signal.

In various embodiments, the method further includes determining the resistance of the electrical component by analyzing the difference between the measured return signal with the first signal; and determining the resistance of the precision resistance standard by analyzing the difference between the measured return signal with the second signal.

In various embodiments, comparing the measured return signal of the first signal with the measured return signal of the second signal comprises comparing the resistance of the electrical component with the resistance of the precision resistance standard.

In various embodiments, the electrical component comprises an electrical wire or a wire harness assembly.

Various embodiments provide a continuity detector for determining the continuity of an electrical wire or harness assembly. The continuity detector can include a handheld housing assembly defining an interior volume; an electronics package disposed within the interior volume defined by the housing assembly, the electronics package comprising a resistance measurement device and a comparator circuit; one or more pass/fail indicators electrically coupled to the electronics package and disposed on the housing assembly or in the housing assembly; a first test contact and a second test contact configured to interface with the electrical wire or harness assembly, wherein the first test contact and the second test contact are external to the interior volume, wherein the first test contact and the second test contact are electrically coupled to the electronics package; a precision resistance standard disposed within the housing and electrically coupled to the electronics package; a power source disposed within the housing assembly, wherein the power source is electrically coupled to the electronics package; wherein the electronics package is configured to send a first signal to the first test contact and to measure a return signal at the second test contact, and the electronics package is configured to send a second signal to the precision resistance standard and to measure the signal after the precision resistance standard; and wherein the comparator circuit is configured to compare a return signal measured by the second test contact with a second return signal measured across the precision resistance standard from the first signal.

This summary is an overview of some of the teachings of the present application and is not intended to be an exclusive or exhaustive treatment of the present subject matter. Further details are found in the detailed description and appended claims. Other aspects will be apparent to persons skilled in the art upon reading and understanding the following detailed description and viewing the drawings that form a part thereof, each of which is not to be taken in a limiting sense. The scope herein is defined by the appended claims and their legal equivalents.

### BRIEF DESCRIPTION OF THE FIGURES

Aspects may be more completely understood in connection with the following figures (FIGS.), in which:

FIG. 1 is a perspective view of a continuity detector in accordance with various embodiments provided herein.

FIG. 2 is a perspective view of a continuity detector testing a wire in the Unit Under Test (UUT) in accordance with various embodiments provided herein.

FIG. 3 is a schematic representation of a continuity detector in accordance with various embodiments provided herein.

FIG. 4 is a schematic representation of a four-wire, Kelvin double bridge circuit in accordance with various embodiments provided herein.

FIG. 5 is a flowchart depicting a method in accordance with various embodiments provided herein.

While embodiments are susceptible to various modifications and alternative forms, specifics thereof have been shown by way of example and drawings, and will be described in detail. It should be understood, however, that the scope herein is not limited to the particular aspects described. On the contrary, the intention is to cover modifications, equivalents, and alternatives falling within the spirit and scope herein.

### DETAILED DESCRIPTION

Embodiments herein provide a calibrated continuity detector. The calibrated continuity detector can determine the continuity between two points, such as if the two points are electrically connected or not. In addition to determining if the two points are electrically connected, the continuity detector can also determine how the resistance between the two points compares to a threshold resistance. In some cases, two points can be electrically connected to each other, but an error in the wiring still exists. The comparison of the measured resistance to a threshold value can ensure the two points are correctly wired.

In various embodiments, the continuity detector can include two contacts or probes. The contacts can be attached to, placed against, or otherwise in electrical communication with two points that are intended to be electrically connected to each other. The resistance between the two points can be measured to determine if the resistance is equal to or less than a threshold value.

The threshold value can vary in different situations. As an example, a user in a first scenario might be expecting the resistance to be less than 12 ohms between two points, whereas a different user using a different detector in a different scenario might be expecting the resistance to be less than 10 ohms. In various embodiments, the threshold value can be preset. In various embodiments, the threshold value is fixed, such that it cannot be changed or modified. In various embodiments, the detector can include a precision resistance standard that is equal to or defines the threshold value for a given continuity detector.

The continuity detector can be configured to determine if the resistance between two points is equal to or less than a desired resistance (i.e. the threshold value). If the resistance is equal to or less than the threshold value then it can be concluded that the two points are properly connected electrically. If the resistance is greater than the threshold value then it can be determined that a problem exists, such as the two points not being wired correctly.

If the resistance is equal to or less than the threshold, then the device can provide an output, such as an output that represents a PASS or a properly wired/connected test point. In some embodiments, the output can be a visual output, such as an illuminated lightbulb or light emitting diode (LED). In some embodiments, the output can be an audible output, such as a buzzer or alarm. In various embodiments, the output can be binary, such as to only indicate a pass (i.e., resistance is equal to or less than the threshold) or a fail (i.e., the resistance is greater than the threshold). In various embodiments, the device does not provide an output for a fail and the device provides an output for a pass. In other embodiments, the device does not provide an output for a pass and the device provides an output for a fail. In other embodiments, the output can include an output of a first type (e.g., audio or visual) for a pass and an output of a different type (e.g., audio or visual) for a fail. In other embodiments, the same type of output (audio or visual) can be used for a pass and fail. In such cases, the audio or visual output can differ such that a user can distinguish between a pass and a fail. As an example, an illuminated red LED can represent a fail and an illuminated green LED can represent a pass. As another example, an audible buzz can represent a fail and an audible chime can represent a pass. In various embodiments, the continuity detector does not display any measured or calculated values, such as current, resistance, or voltage.

In various embodiments, the continuity detector can include a precision resistance standard, such as a resistor with a known value. The precision resistance standard can be selected to have a resistance equivalent to the threshold value. The threshold value can be defined by a user or a product specification. In various embodiments, the precision resistance standard can be defined prior to manufacturing or assembling the continuity detector, such that a precision resistance standard of a correct size can be included in the detector. In various embodiments, the resistance value of the precision resistance standard is fixed and cannot be adjusted by a user for a specific detector.

In various embodiments, the continuity detector can send a known electrical signal, such as to the first contact of the detector that is electrically connected to the first point of the UUT. The continuity detector can measure the returning electrical signal at the second point of the UUT with the second contact. Further, within the detector, the same known electrical signal that is sent to the first contact can also be sent to the precision resistance standard. The electrical signal on the other side of the precision resistance standard can be measured, similar to the measurement of the electrical signal at the second point of the UUT. The measured electrical signal on the other side of the precision resistance standard can be compared to the electrical signal at the second point of the UUT. The two measured electrical signals can be compared to determine if the resistance between the two points is equal to or less than the resistance of the precision resistance standard.

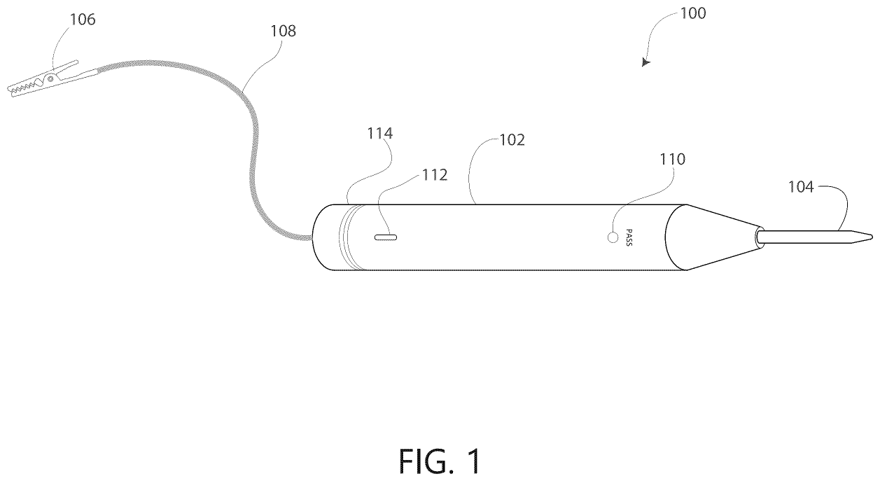

In reference now to the figures, FIG. 1 shows a perspective view of a continuity detector 100 in accordance with various embodiments provided herein. In various embodiments, the continuity detector 100 can include a handheld housing 102. The handheld housing 102 can define an interior volume. In various embodiments, the housing 102 can include an ingress protection rating of at least IP54. In various embodiments, the interior volume can contain the circuitry of the test system (i.e. an electronics package of the detector). While FIG. 1 shows a pencil-type detector, it is understood that the housing 102 can be in the form of many other mechanical configurations.

The detector 100 can include a first probe or contact 104 and a second probe or contact 106. In various embodiments, a probe 104, 106 can be removable, and can be replaced with various styles of electrical contacts. In various embodiments, the first probe 104 can provide a positive side of the test, and a second probe 106 can be provide the negative or “return” side of the test.

In various embodiments, the first probe 104 can be directly connected to the front of the housing 102, such as shown in FIG. 1. In other embodiments, the first probe 104 can be connected to a lead. In some embodiments, the lead can be disposed within the housing and in other embodiments the lead can be at least partially disposed external to the housing 102. In various embodiments, the second probe 106 can be connected to the back of the housing 102 either directly or via a lead 108. In some embodiments, the lead 108 can be disposed within the housing and in other embodiments the lead 108 can be at least partially disposed external to the housing 102, such as shown in FIG. 1. In various embodiments, the handheld housing assembly further comprises an ergonomic grip surface to facilitate comfortable manual operation. In various embodiments, the housing assembly further comprises a belt clip for attachment to a user's clothing or tool belt. In various embodiments, the housing 102 is formed from a material having a dielectric strength of at least 20 kV/mm.

In various embodiments, each of the leads or contacts can contain two separate electrical conductors to allow for a four-wire (Kelvin) connection as close as practical to the Unit Under Test (UUT) so as to eliminate the test lead resistance from the measurement. In various embodiments, the lead 108 can be terminated in a probe 106. In various embodiments, a probe 104, 106 can take the form of a contact or a clip. In various embodiments, the probe 104, 106 can be replaceable. In various embodiments, the first test contact and the second test contact (i.e., probes 104, 106) can be color-coded to indicate polarity or connection order.

In various embodiments, the detector 100 can include an output device 110, such as a visual output device, an audible output device, and/or a haptic output device. In some embodiments, the output device 110 can include a visual output device, such as an indicator lamp or LED. In various embodiments, the output device 110 can include an audible output device, such as an acoustic “buzzer”, alarm, chime, bell, or beeper. In some embodiments, the output device 110 can provide haptic feedback to a user, such as by including and activating a vibration motor.

The output device 110 can provide an indication of a test PASS condition, such that the detector 100 only activates the output device 110 for a passing test condition. In other embodiments, the output device 110 can provide an indication of a test FAIL condition, such that the detector 100 only activates the output device 110 for a failing test condition (e.g., the resistance of the UUT is greater than the threshold).

In various embodiments, the detector 100 can further include a port 112, such as a Universal Serial Bus (USB) port. The port 112 can be utilized for the purpose of charging a power source, such as an internal rechargeable power cell. In other embodiments, this port may be eliminated, and a non-rechargeable power source can be provided as alternative to the rechargeable power source. The power source can be disposed within the interior volume of the housing and can be electrically coupled to the electronics package to supply operating power. The continuity detector can further include an internal protection circuit configured to monitor charging and discharging of the power source, such that overcurrent, overvoltage, or undervoltage conditions do not adversely impact circuit operation. In various embodiments, the power source can include a battery. The term “battery” can refer to multiple cells, in the vernacular, the term “battery” can also be used for a single power cell and will therefore be used here to describe the power source regardless of the number of cells. As such, an internal power source can include a battery, such as a rechargeable battery or a non-rechargeable (primary) battery, such as an AA size alkaline battery. In various embodiments, the housing 102 can include a removable end cap 114. In various embodiments, the electronics package is configured to automatically power off after a predetermined period of inactivity to conserve battery life. In various embodiments, the electronics package further comprises a low-battery indicator disposed on or in the housing assembly. The removable end cap 114 can allow the battery to be replaced when its capacity has been depleted.

Other options for the internal power source are also possible. In various embodiments, the power source for the continuity detector can comprise a lithium-ion (Li-ion) battery. In further embodiments, the power source can be a lithium polymer (LiPo) battery or a nickel-metal hydride (NiMH) rechargeable battery. In various embodiments, when a nickel-metal hydride battery is used, the housing can include a compartment configured to receive one or more AA or AAA size NiMH cells, and a corresponding charging circuit compatible with nickel-metal hydride cell chemistries.

In other embodiments, the power source is a non-rechargeable lithium primary cell, such as a CR123A or CR2 lithium battery. The use of lithium primary cells can provide extended operational life relative to alkaline batteries for similar form factors due to the higher energy density available from lithium chemistry. The housing can be designed to enable easy replacement of such primary lithium batteries via a tool-less or threaded end cap.

In some embodiments, alternative power sources can be employed, such as zinc-air primary batteries, button cell batteries, or sealed lead-acid batteries, depending on the target application and size constraints of the continuity detector. The electronics package can also be configured for compatibility with external power supplied via a DC barrel jack or similar connector for scenarios where line-powered operation is advantageous, such as extended test durations or continuous operation in a production environment.

In certain embodiments, power management features can include an integrated voltage regulator or DC-DC converter configured for the nominal voltage range of the selected battery type. A battery status monitoring circuit, such as a fuel gauge integrated circuit or a voltage divider coupled to an analog-to-digital converter within the microcontroller, can be included to provide battery state-of-charge information for activation of a low-battery indicator or for automated power-down functions.

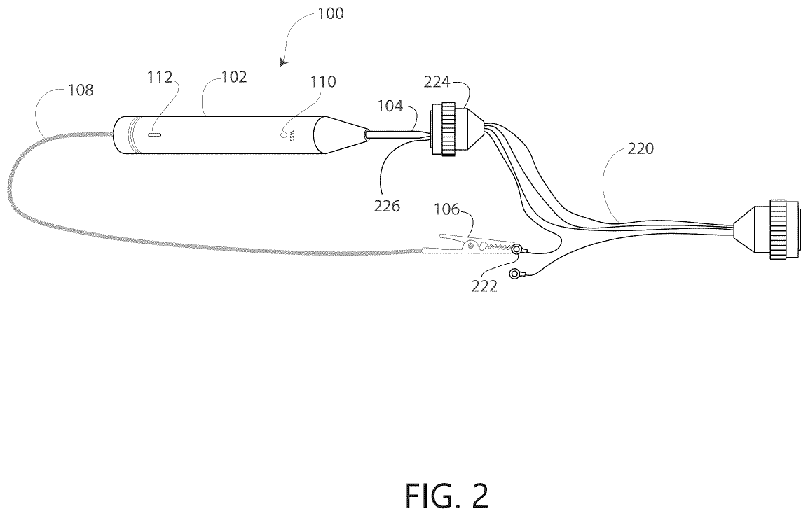

In reference now to FIG. 2, a continuity detector 100 is shown checking the continuity of a UUT 220 in the form of a wire harness. In a testing scenario, the first probe 104 can contact a first point 226 on one end of the UUT 220, while the second probe 106 contacts a second point 222 on the other end of the same wire in the UUT 220. In some variations of the UUT 220, one, or both ends of the wire being tested may be a contact in a connector 224, or an “unterminated” contact, or a contact terminated with a contact “lug,” such as the second point 222 is shown in FIG. 2.

If the resistance of the wire under test is less than or equal to the resistance of the reference resistor (i.e. precision resistance standard), then a PASS indicator (e.g., output device 110) can illuminate or make an audible sound. If the resistance of the wire under test is greater than the resistance of the reference resistor, then the PASS indicator will not be illuminated, nor will an audible output be produced. In other embodiments, a different audible or visual output can be produced for a failure.

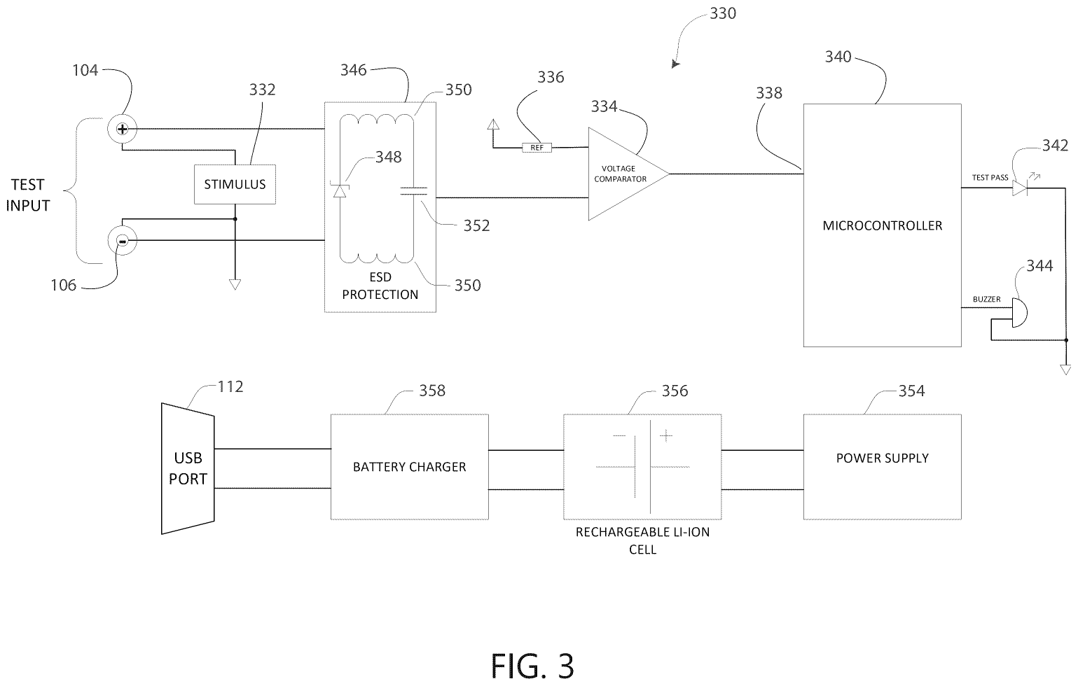

In reference now to FIG. 3, a block diagram of an electronics package 330 is shown. The electronics package 330 can be at least partially disposed within an interior volume defined by the housing 102. Specific component values, and components that are ancillary to the functions of the design blocks have not been included for the purpose of clarity. It is also possible for such components to be included in any specific embodiments disclosed herein, and proper component values and configurations necessary to implement said design blocks can be implemented.

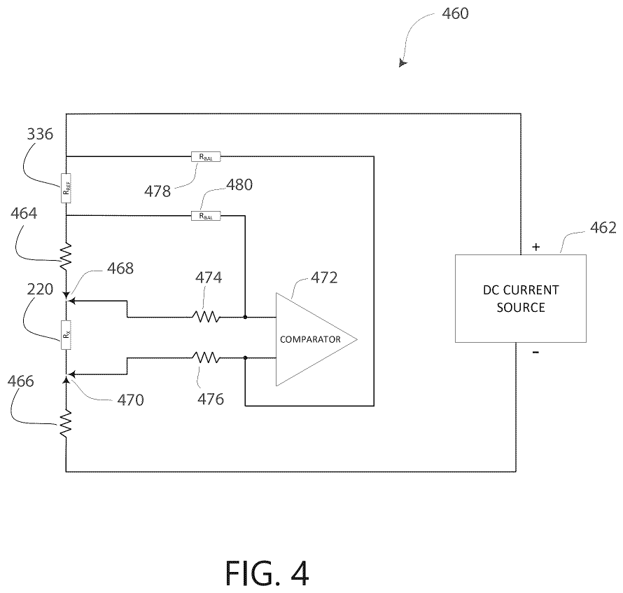

In various embodiments, a first lead can be connected to the first probe 104 and a second lead can be connected to the second probe 106. The test leads can be connected to a stimulus source 332 which can be configured to provide a constant current, such as an output signal through the UUT. In parallel to this stimulus source 332, a measurement circuit consisting of a voltage comparator 334 can be used to determine if the UUT resistance is above or below the value of a precision resistance standard 336 (i.e. a reference resistor). In many embodiments, this design can implement a Kelvin double bridge circuit as detailed in FIG. 4.

In various embodiments, the precision resistance standard 336 is at least 2 ohms, 3 ohms, 4 ohms, 5 ohms, 6 ohms, 7 ohms, 8 ohms, 9 ohms, 10 ohms, 11 ohms, 12 ohms, 13 ohms, 14 ohms, 15 ohms, or 20 ohms. In some embodiments, the precision resistance standard is no more than 50 ohms, 45 ohms, 40 ohms, 35 ohms, 30 ohms, 25 ohms, 20 ohms, 15 ohms, or 10 ohms. In various embodiments, the precision resistance standard can fall in a range bounded by any of the values provided herein.

The output of the comparator 334 can be tied to a digital or analog input 338 of a microcontroller 340 that determines if the test is passing or failing. If the test passes, the microcontroller activates an output device 110 (e.g., pass/fail indicator), such as by illuminating an LED 342 or activating an audible output 344. Once the resistance between the two test inputs (probes 104, 106) is greater than the calibration reference value, such as by disconnecting one of the probes, the output device 110 can be terminated or silenced.

In various embodiments, there are a multitude of designs in which no digital circuits or microcontroller is needed. Other embodiments can connect the reference resistor 336 to the same contacts as the UUT 220 using a double-pole, double-throw switch to create a reference signal to compare to the UUT 220. Such designs are included in the present disclosure.

In various embodiments, the electronics package 330 can include an electrostatic discharge (ESD) protection block 346. The ESD protection block 346 can be used to assure that an electro-static discharge to either of the positive or negative test leads does not damage the remaining analog and/or digital components in the detector 100. There can be numerous methods for ESD protection, various embodiments include devices such as a transient voltage suppression diode (TVS) 348 in parallel to the inputs followed by inductors 350 in series with the inputs, with a discharge capacitor 352 in parallel to the inductors 350. While such designs can slow the reaction to changes in the inputs, given that the detector can be operated manually, the reaction times should be well within the limits of human perception.

In various embodiments, the electronics package includes a temperature compensation circuit to account for resistance changes due to ambient temperature variations.

A power source is required to provide the test current and reference voltage used by the comparator 334, and to power the microcontroller 340, the LED 342, and the optional buzzer 344. In various embodiments, this power is supplied by a DC-to-DC converter power supply 354, which is in turn powered by a battery 356, such as a rechargeable battery. The battery 356 can be charged via a battery charging circuit 358, which might be an integrated circuit (IC) charger powered from a port 112, such as a standard Universal Serial Bus (USB) port connector.

In other embodiments, power can be supplied via a non-rechargeable battery, such as an alkaline AA cell, or similar primary cell, thus eliminating the charging circuit 358 and the port 112, but requiring easy access for battery replacement, using, for example, a threaded cap 114 at one end of the housing 102.

In reference now to FIG. 4, a schematic representation of a Kelvin double bridge 460 which can be incorporated into various embodiments disclosed herein is provided. The Kelvin double bridge can be used to eliminate the need to compensate for the resistance of long test leads that electrically connect the first probe 104 and the second probe 106 with the remainder of the detector 100.

The test current source 462, which can be a DC current source, can be connected to the UUT 220 through a series circuit consisting of the reference resistor 336, the positive test lead to the first probe 104, represented here by the resistance 464, and the negative test lead to the second probe 106, represented here by the resistance 466. As each of these resistance values are in series, they each cause a voltage drop proportional to their specific resistance relative to the total resistance of all of them in series. When each of the test leads to probes 104 and 106, contain a second wire 468 and 470, in parallel to the wires 464 and 466 connected to the source, these wires, together with wires connected in parallel to the reference resistor 336, are in turn connected to a high impedance comparator 472. Because this parallel circuit has a high impedance, such as on the order of 10 megaohms or greater, very little current flows through it, and therefore, the voltage drop across these “sense” wires 474 and 476 is extremely low. This creates a condition where the inputs of the comparator 472 have virtually the same voltage as that at the contacts to the UUT represented by 468 and 470.

The comparator 472 can have balanced inputs when the ratio of the reference resistor 336 to the UUT resistance 220 is equal to the ratio of the opposite legs represented by the resistors 478 and 480. If the resistors 478 and 480 are of equal value, then the bridge is balanced when the UUT 220 is of equal resistance to the reference resistor 336. In this way, the pass/fail limit for the device can be set by simply choosing the appropriate reference resistor 336.

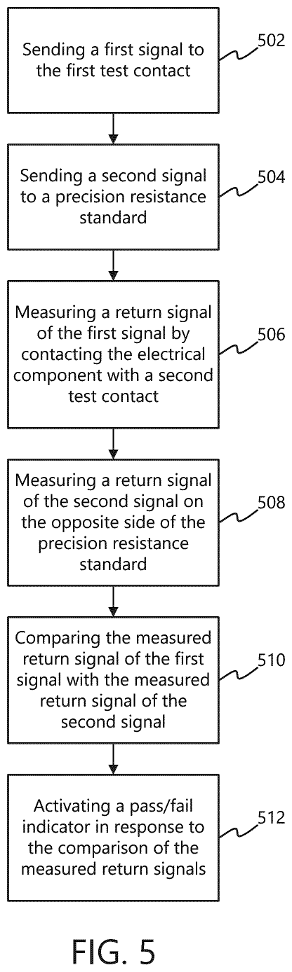

With reference to FIG. 5, a method of determining the continuity of an electrical component using a calibrated continuity detector is provided. The method can begin by contacting the component under test with a first test contact of the continuity detector, or otherwise placing the first test contact in electrical communication with the component under test. The electronics package disposed within the continuity detector then sends a first signal to the first test contact (operation 502), which, through the electrical component, is accessible for measurement at another point of contact. Substantially concurrently or in sequence, the electronics package sends a second signal to an internal precision resistance standard (operation 504), the value of which is predetermined to establish a threshold for pass/fail determination. In some embodiments, the first signal and the second signal can be identical. In some embodiments, the first signal and the second signal can be the same signal sent at the same time. As the first signal traverses the electrical component, a return signal corresponding to that signal is measured by contacting the component with a second test contact of the continuity detector (operation 506). Simultaneously, the system measures a return signal of the second signal after it has traversed the precision resistance standard, specifically recording the signal at the side of the resistance standard opposite to where the signal was initially applied (operation 508).

Subsequently, the measured return signal of the first signal, indicative of the resistance across the electrical component under test, is compared to the measured return signal of the second signal, which reflects the resistance across the precision resistance standard (operation 510). This direct comparison allows the electronics package, optionally via a comparator circuit and/or associated microcontroller, to determine whether the resistance of the component under test is greater than, equal to, or less than the known threshold set by the precision resistance standard. Based on the result of this comparison, a pass/fail indicator is activated (operation 512). The pass/fail indicator may comprise a visual output, such as a light emitting diode (LED), an audible output, such as a buzzer, or both, thereby providing a binary indication to a user that the electrical continuity of the component under test meets or fails the predetermined resistance criteria. This method ensures both rapid and calibrated determination of electrical continuity in accordance with the precision threshold as set by the internal resistance standard.

The embodiments described herein are not intended to be exhaustive or to limit the invention to the precise forms disclosed in the following detailed description. Rather, the embodiments are chosen and described so that others skilled in the art can appreciate and understand the principles and practices. As such, aspects have been described with reference to various specific and preferred embodiments and techniques. However, it should be understood that many variations and modifications may be made while remaining within the spirit and scope herein.

1. A continuity detector for determining the continuity of an electrical wire or harness assembly, the continuity detector comprising:
(a) a handheld housing assembly defining an interior volume;
(b) an electronics package disposed within the interior volume defined by the housing assembly, the electronics package comprising a resistance measurement device and a comparator circuit;
(c) one or more pass/fail indicators electrically coupled to the electronics package and disposed on the housing assembly or in the housing assembly;
(d) a first test contact and a second test contact configured to interface with the electrical wire or harness assembly, wherein the first test contact and the second test contact are external to the interior volume, wherein the first test contact and the second test contact are electrically coupled to the electronics package;
(e) a precision resistance standard disposed within the housing and electrically coupled to the electronics package;
(f) a power source disposed within the housing assembly, wherein the power source is electrically coupled to the electronics package;
wherein the electronics package is configured to send a first signal to the first test contact and to measure a return signal at the second test contact, and the electronics package is configured to send a second signal to the precision resistance standard and to measure the signal after the precision resistance standard; and
wherein the comparator circuit is configured to determine if the resistance of the electrical wire or the harness assembly is greater than, less than, or equal to the resistance of the precision resistance standard.

2. The continuity detector of claim 1, wherein the first signal and the second signal are identical.

3. The continuity detector of claim 1, wherein the one or more pass/fail indicators are activated only if the resistance of the electrical wire under test or the harness assembly under test is less than or equal to the resistance of the precision resistance standard.

4. A system according to claim 1, wherein the comparator circuit is configured to directly compare the resistance of the precision resistance standard to the resistance of the electrical wire or the wire harness assembly.

5. The continuity detector of claim 4, wherein first test contact and the second test contact are connected via a Kelvin connection comprising four-wire test leads, such that the resistance of the test contacts does not impact the measurement of resistance or the comparison of resistance.

6. The continuity detector of claim 1, wherein the precision resistance standard is at least 5 ohms and not more than 25 ohms.

7. The continuity detector of claim 1, wherein the one or more pass/fail indicators comprise at least one of a visual indicator or an audible indicator.

8. The continuity detector of claim 9, wherein the visual indicator comprises a light emitting diode (LED).

9. The continuity detector of claim 1, wherein the pass/fail indicators provide a binary output, indicating only a pass or a fail condition to a user.

10. The continuity detector of claim 1, wherein the continuity detector does not display a numerical resistance value to a user.

11. The continuity detector of claim 1, wherein at least one of the first test contact or the second test contact is removably attached to the housing assembly.

12. The continuity detector of claim 1, wherein the precision resistance standard is a resistor selected during manufacture to define the threshold resistance for a predetermined application.

13. The continuity detector of claim 1, wherein the electronics package comprises a microcontroller configured to receive an output from the comparator circuit and to activate the one or more pass/fail indicators based on whether the measured resistance is less than or equal to the resistance of the precision resistance standard.

14. The continuity detector of claim 1, wherein the electronics package comprises a current source configured to supply a constant current through the electrical wire or harness assembly under test.

15. The continuity detector of claim 1, wherein the first test contact and the second test contact are each connected to the electronics package by flexible leads.

16. A continuity detector for determining the continuity of an electrical wire or harness assembly, the continuity detector comprising:
(a) a handheld housing assembly defining an interior volume;
(b) an electronics package disposed within the interior volume defined by the housing assembly, the electronics package comprising a resistance measurement device and a comparator circuit;
(c) one or more pass/fail indicators electrically coupled to the electronics package and disposed on the housing assembly or in the housing assembly;
(d) a first test contact and a second test contact configured to interface with the electrical wire or harness assembly, wherein the first test contact and the second test contact are external to the interior volume, wherein the first test contact and the second test contact are electrically coupled to the electronics package;
(e) a precision resistance standard disposed within the housing and electrically coupled to the electronics package;
(f) a power source disposed within the housing assembly, wherein the power source is electrically coupled to the electronics package;
wherein the electronics package is configured to send a first signal to the first test contact and to measure a return signal at the second test contact, and the electronics package is configured to send a second signal to the precision resistance standard and to measure the signal after the precision resistance standard; and
wherein the comparator circuit is configured to compare a return signal measured by the second test contact with a second return signal measured across the precision resistance standard from the first signal.

17. A method for determining the continuity of an electrical component, comprising:
contacting the electrical component with a first test contact of a continuity detector;
sending a first signal from an electronics package within the continuity detector to the first test contact;
sending a second signal to a precision resistance standard within the continuity detector;
measuring a return signal of the first signal by contacting the electrical component with a second test contact of the continuity detector;
measuring a return signal of the second signal on the opposite side of the precision resistance standard from where the second signal was sent;
comparing the measured return signal of the first signal with the measured return signal of the second signal; and
activating a pass/fail indicator in response to the comparison of the measured return signals.

18. The method of claim 17, wherein the first signal and the second signal are sent at the same time.

19. The method of claim 17, wherein the first signal and the second signal are the same signal.

20. The method of claim 17, wherein the electrical component comprises an electrical wire or a wire harness assembly.
